(19) United States
(12) Patent Application Publication
(10) Pub. No.: US 2024/0106396 A1
(43) Pub. Date: Mar. 28, 2024

(54) Push-Pull Amplifying Unit and Doherty Amplifier Comprising the Same

(71) Applicant: TECHNISCHE UNIVERSITEIT DELFT, Delft (NL)

(72) Inventors: Mohammad Reza BEIKMIRZA, Delft (NL); Seyed Morteza ALAVI, Delft (NL); Leonardus Cornelis Nicolaas DE VREEDE, Delft (NL); Freerk VAN RIJS, Delft (NL); Radjindrepersad GAJADHARSING, Delft (NL)

(21) Appl. No.: 18/264,300

(22) PCT Filed: Feb. 4, 2022
(86) PCT No.: PCT/NL2022/050058

§ 371 Date: Aug. 4, 2023

(30) Foreign Application Priority Data
Feb. 5, 2021 (NL) 2027508

(51) Int. Cl. H03F 1/02; H01L 23/66; H03F 1/56; H03F 3/195; H03F 3/26

(52) U.S. Cl. CPC H03F 1/0288; H01L 23/66; H03F 1/565; H03F 3/195; H03F 3/265; H01L 2223/6611; H01L 2223/665; H01L 2223/6655; H03F 2200/06; H03F 2200/451

(57) ABSTRACT

The present invention relates to a push-pull amplifying unit and a Doherty amplifier. The push-pull amplifying unit comprises a first amplifier, a second amplifier, a first shunt inductor, and a second shunt inductor. The first and second shunt inductors have mutually connected second terminals and are inductively coupled to increase the impedance between the first output and the virtual ground and the impedance between the second output and the virtual ground at a fundamental frequency of a signal to be amplified by the push-pull amplifying unit relative to those impedances in the absence of said inductive coupling, and to decrease the impedance between the first output and the virtual ground and the impedance between the second output and the virtual ground at a second harmonic frequency of the signal to be amplified relative to those impedances in the absence of said inductive coupling.

The present invention relates to a push-pull amplifying unit. The present invention further relates to a Doherty amplifier comprising the same.

Push-pull amplifying units are known in the art. These units comprise a first amplifier having a first output, and a second amplifier having a second output. The first amplifier and second amplifier are fed with identical signals that have a mutual phase offset of 180 degrees.

Both the first amplifier and second amplifier are generally non-linear devices. Accordingly, at the outputs of these amplifiers, higher order harmonics will be present. For some application areas, these higher order components are unwanted. To suppress these harmonics from occurring at the output of the amplifier, techniques such as pre-distortion and harmonic filtering are known.

Harmonic filtering can be realized by presenting a suitable impedance, i.e. a short, at the unwanted harmonic frequency. However, such filtering should not prevent a suitable load impedance to be presented at the fundamental frequency.

The first and second amplifiers further require biasing, both at the input and the output. These biasing networks should not disturb the RF performance of the amplifiers.

An ever-continuing trend in the art is to realize all the functionality described above in the smallest solution possible.

An object of the present invention is to provide a push-pull amplifying unit with which such compactness can be achieved without degrading the performance associated with the various functionalities or at least to a lesser extent.

According to the present invention, this object is achieved with a push-pull amplifying unit as described in claim 1, which comprises a first shunt inductor having a first terminal thereof connected to the first output and a second shunt inductor having a first terminal thereof connected to the second output. The first and second shunt inductors each have a second terminal, wherein the second terminals of the first and second shunt inductors are electrically connected at a virtual RF ground, which, during use, is RF grounded.

According to the present invention, the first and second shunt inductors are inductively coupled to increase the impedance between the first output and the virtual ground and the impedance between the second output and the virtual ground at a fundamental frequency of a signal to be amplified by the push-pull amplifying unit relative to those impedances in the absence of said inductive coupling. Furthermore, the first and second shunt inductors are inductively coupled to decrease the impedance between the first output and the virtual ground and the impedance between the second output and the virtual ground at a second harmonic frequency of the signal to be amplified relative to those impedances in the absence of said inductive coupling.

A DC biasing network can be connected to the virtual ground without affecting RF behavior of the first and second amplifiers. Furthermore, the use of coupled inductors allows a proper impedance to be realized at the fundamental frequency while simultaneously, i.e. using the same components, realizing a relatively low impedance at the second harmonic frequency and/or other even harmonic frequencies.

The inductive coupling between the first shunt inductor and the second shunt inductor may be described by a mutual inductance of which a coupling coefficient has a magnitude of at least 0.5, more preferably, 0.7 and even more preferably 0.9.

The first amplifier comprises a first output capacitance, and the second amplifier a second output capacitance. The first shunt inductor can be configured to resonate with the first output capacitance at a frequency at or close to the fundamental frequency of the signal to be amplified. Similarly, the second shunt inductor can be configured to resonate with the second output capacitance at a frequency at or close to the fundamental frequency of the signal to be amplified. In this manner, the impedance at the fundamental frequency at the intrinsic output of the first and second amplifiers, e.g. the intrinsic drains, can be close to a real impedance, whereas low impedances are presented at the second harmonic frequency.

The first and second inductors can be realized in various manners. For example, the first shunt inductor and the second shunt inductor can be formed by one or more loop units connected in a chain of loop units in an order from a first loop unit to a last loop unit. Each loop unit may comprise a first loop part having a first end and a second end, and a second loop part having a third end and a fourth end, the first and second loop parts being arranged opposite to each other in a respective first direction. Among the one or more loop units, the first end of the first loop part of a first loop unit in the chain of loop units may form the first terminal of the first shunt inductor and the third end of the second loop part of the first loop unit may form the first terminal of the second shunt inductor. Furthermore, among the one or more loop units, the second end of the first loop part of a last loop unit in the chain of loop units is electrically connected to the fourth end of the second loop part of the last loop unit for forming the virtual RF ground.

For each given loop unit among the one or more loop units other than the last loop unit, each second end of the first loop part may be electrically connected to the third end of the second loop part of a loop unit that directly follows said given loop unit in the chain of loop units. Additionally, each fourth end of the second loop part may be electrically connected to the first end of the first loop part of the loop unit that directly follows said given loop unit in the chain of loop units. Furthermore, for said each given loop unit other than the last loop unit, the first loop part may be arranged adjacent, in a second direction perpendicular to the first direction, to a second loop part of the loop unit that directly follows said given loop unit in the chain of loop units.

Each pair of directly following loop units in the chain of loop units can be 8-shaped. It should be noted that the loop parts may extend in several metal layers in a metal layer stack. Furthermore, the connection between the various loop units may occur on different metal layers to avoid short circuits. The present invention is furthermore not limited to 8-shaped pairs of loop units; other shapes are equally possible.

Alternatively, the first shunt inductor may comprise a first horizontally extending planar loop part and the second shunt inductor may comprise a second horizontally extending planar loop part, wherein the first and second planar loop parts are vertically spaced apart and are at least partially horizontally overlapping.

Alternatively, the first shunt inductor and the second shunt inductor can be each formed by one or more bondwires, wherein the one or more bondwires of the first shunt inductor preferably extend parallel to the one or more bondwires of the second inductor.

The push-pull amplifying unit may further comprise a semiconductor die on which the first amplifier and second amplifier are integrated, each of the first and second amplifier being formed as a multi-finger field-effect transistor. The field-effect transistors of the first amplifier and second amplifier can be interleaved. In this case, gate runners corresponding to the multi-finger field-effect transistor of the first amplifier can be connected to a first gate terminal, gate runners corresponding to the multi-finger field-effect transistor of the second amplifier to a second gate terminal, drains corresponding to the multi-finger field-effect transistor of the first amplifier to a first drain terminal, and drains corresponding to the multi-finger field-effect transistor of the second amplifier to a second drain terminal. Furthermore, the first drain terminal can be electrically connected to the first terminal of the first shunt inductor, and the second drain terminal to the first terminal of the second shunt inductor.

Within the context of the present invention, an interleaved configuration of multi-finger field-effect transistors should be interpreted as a single active block in which the gate runners and drains of the two field-effect transistors extend along a same direction and in which the gate runners and drains of one field-effect transistor are arranged alternately with the gate runners and drains of the other field-effect transistor. Typically, both field-effect transistors share a same source, which is typically grounded during operation through the substrate. For example, a possible finger configuration could be S-G1-D1-G1-S-G2-D2-G2-S, wherein S represents a source region, G1 a gate runner of a first field-effect transistor, D1 a drain finger of the first field-effect transistor, G2 a gate runner of a second field-effect transistor, and D2 a drain finger of the second field-effect transistor.

The first drain terminal, the second drain terminal, the first gate terminal, and the second gate terminal, can be each formed by rectangular bars that are elongated in a direction perpendicular to the gate runners of the multi-finger field-effect transistors of the first amplifier and second amplifier.

The push-pull amplifying unit may further comprise a DC biasing network connected to the virtual RF ground and configured for supplying a DC bias to the first output and second output. This DC biasing network may comprise a shunt capacitor arranged in between the virtual ground and ground that is configured for providing a short at RF frequencies. The DC biasing network may further be connectable to or comprise a feeding line that is connected or connectable to a DC biasing source.

The push-pull amplifying unit may further comprise an input balun having an unbalanced input port for receiving the signal to be amplified, a first balanced output port connected to an input of the first amplifier, and a second balanced output port connected to an input of the second amplifier. The signals to be fed to the first and second amplifier are typically offset by 180 degrees at the fundamental frequency.

The push-pull amplifying unit of the present invention may be used in various semiconductor technologies such as silicon based laterally diffused metal-oxide-semiconductor, LDMOS, technologies, or gallium nitride field-effect transistor technologies. The push-pull amplifying unit of the present invention can be used in a frequency range between 10 MHz and 40 GHz, and is particularly suitable to be used in frequency bands allocated for mobile telecommunications such as 4G, 5G or 6G.

According to a second aspect, the present invention provides a Doherty amplifier that includes a main amplifier comprising a push-pull amplifying unit as defined above and a peak amplifier also comprising a push-pull amplifying unit as defined above. It should be noted that the present invention is not limited to a single peak amplifier. More in particular, the present invention can be equally used in n-way Doherty amplifiers, with n>2. In addition, the present invention can be used in Doherty amplifiers in which the main and peak amplifiers have the same or a different power generating capability.

The Doherty amplifier of the present invention further comprises a first impedance inverter connected between a first combining node and the first output of the push-pull amplifying unit of one of the main amplifier and peak amplifier and a second impedance inverter connected between a second combining node and the second output of the push-pull amplifying unit of said one of the main amplifier and peak amplifier. The present invention equally relates to Doherty amplifiers of the regular type having the impedance inverter connected to the main amplifier, as to Doherty amplifiers of the inverted type having the impedance inverter connected to the peak amplifier.

The Doherty amplifier may further comprise a balun having a first balanced input connected to the first combining node, a second balanced input connected to the second combining node, and an unbalanced output connected to an output of the Doherty amplifier. According to the present invention, the second output of the push-pull amplifying unit of the other of said main amplifier and peak amplifier is electrically connected to the first combining node, and the first output of the push-pull amplifying unit of said the other of said main amplifier and peak amplifier is connected to the second combining node.

The Doherty amplifier may comprise a Doherty splitter configured to split a signal to be amplified into a first signal part and a second signal part, wherein the second signal part has a phase offset of 90 degrees relative to the second signal part. The Doherty amplifier of the present invention may further comprise a first input balun and a second input balun. The first input balun has an unbalanced input port for receiving the first signal part from the Doherty splitter. The first input balun is configured for outputting a signal emerging at its first balanced output port to the first amplifier of the amplifying unit of the main amplifier, and for outputting a signal emerging at its second balanced output port to the second amplifier of the amplifying unit of the main amplifier. The second input balun has an unbalanced input port for receiving the second signal part from the Doherty splitter. The second input balun is configured for outputting a signal emerging at its first balanced output port to the first amplifier of the amplifying unit of the peak amplifier, and for outputting a signal emerging at its second balanced output port to the second amplifier of the amplifying unit of the peak amplifier. Typically, both the first and second input balun introduce a phase delay between signals emerging at their first and second balanced output ports of 180 degrees.

The first impedance inverter and the second impedance inverter can each formed by a respective first network, each first network comprising an input shunt inductor between an input node of the first network and the virtual ground or ground, a series capacitor between the input node and an output node of the first network, and an output shunt inductor between the output node and the virtual ground or ground. The first impedance inverter and the second impedance inverter preferably have an electrical length of 90 degrees at the fundamental frequency. The first networks may act as lumped equivalents for quarter-wavelength transmission lines.

In addition, the input shunt inductor of the first network of the first impedance inverter can be electrically connected to the input shunt inductor of the first network of the second impedance inverter. Additionally or alternatively, the output shunt inductor of the first network of the first impedance inverter can be electrically connected to the output shunt inductor of the first network of the second impedance inverter. These connected input shunt inductors and/or connected output shunt inductors can be formed by a chain of loop units as described earlier. Furthermore, the connected input shunt inductors can be incorporated in the first shunt inductor and second shunt inductor. More in particular, the first shunt inductor taken in isolation is arranged in parallel to the input shunt inductor of the first impedance inverter and the second shunt inductor in parallel to the input shunt inductor of the second impedance inverter. Two inductors in parallel can be replaced by a single inductor, thereby reducing the occupied area.

In some embodiments, the first inductor and second inductor may not have the functionality of tuning out the respective output capacitance. In such cases, the input shunt inductor of the first impedance inverter may be substantially identical to the first shunt inductor and the input shunt inductor of the second impedance inverter may be substantially identical to the second shunt inductor.

The Doherty amplifier may further comprise one or more second networks arranged in between the first output of the push-pull amplifying unit of the other of the main amplifier and peak amplifier, and the second combining node, and one or more second networks arranged in between the second output of the push-pull amplifying unit of the other of the main amplifier and peak amplifier and the first combining node. Each second network may comprise an input shunt inductor between an input node of the second network and the virtual ground or ground, a series capacitor between the input node and an output node of the second network, and an output shunt inductor between the output node of the second network and the virtual ground or ground. Also the second networks may act as lumped equivalents for transmission lines of a particular length. Preferably, the combined electrical length of the one or more second networks at the fundamental frequency equals an integer times 180 degrees. In some embodiments, the one or more second networks may be omitted. In these embodiments, the first output of the push-pull amplifying unit of the other of the main amplifier and peak amplifier is connected directly to the second combining node, and the second output of the push-pull amplifying unit of the other of the main amplifier and peak amplifier directly to the first combining node.

The input shunt inductor of that second network which is connected to the first output of the push-pull amplifying unit of the other of the main amplifier and peak amplifier and the input shunt inductor of that second network which is connected to the second output of the push-pull amplifying unit of the other of the main amplifier and peak amplifier can be electrically connected. Additionally or alternatively, the output shunt inductor of that second network which is connected to the first combining node and the output shunt inductor of that second network which is connected to the second combining node can be electrically connected. Furthermore, the connected input shunt inductors of the second networks and/or the connected output shunt inductors of the second networks can be formed by a chain of loop units as defined earlier.

The connected input shunt inductors of the second networks can be incorporated in the first shunt inductor and second shunt inductor of the push-pull amplifying unit of the other of the main amplifier and peak amplifier. Similarly, the connected output shunt inductors of the second networks and the abovementioned connected output shunt inductors of the first networks can ne combined.

The balun may comprise a first inductive part arranged between the first balanced input and the second balanced input, and a second inductive part having one terminal connected to ground and another terminal to the output of the Doherty amplifier. The second inductive part can be electromagnetically coupled with the first inductive part. The first and second inductive parts can be formed using coupled lines, such as a Marchand balun. Moreover, the first inductive part can be combined with the connected output shunt inductors of the first networks and/or the connected output shunt inductors of the second networks. In other embodiments, the unbalanced port can be connected to a load having a capacitive part, wherein an input impedance of the balun between the first and second balanced ports due to the capacitive part has an inductive part that at least partially forms the connected output shunt inductors of the first networks and/or the connected output shunt inductors of the second networks.

Next, the present invention will be described in more detail referring to the appended drawings, wherein:

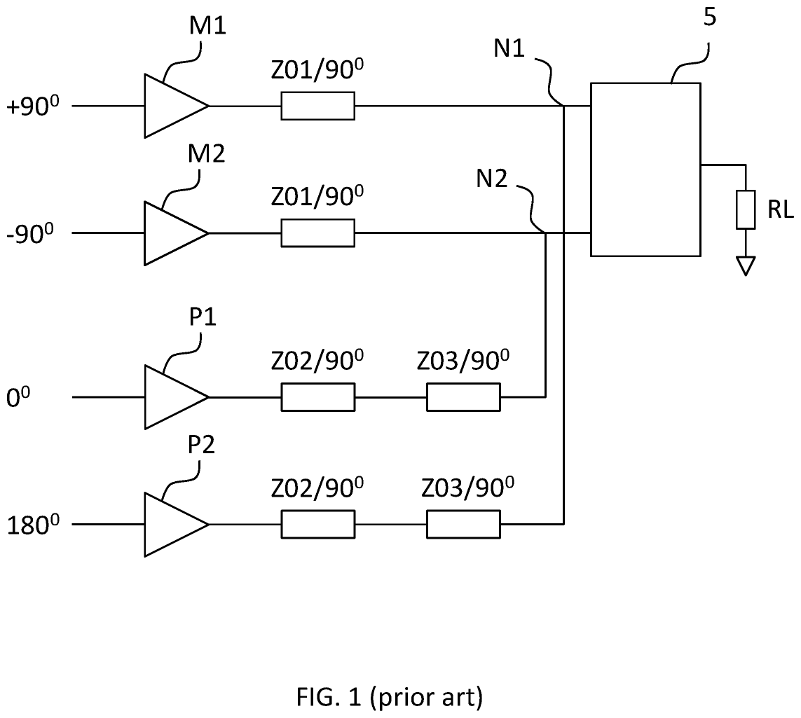

FIG. 1 illustrates a known example of a balanced 2-way Doherty amplifier;

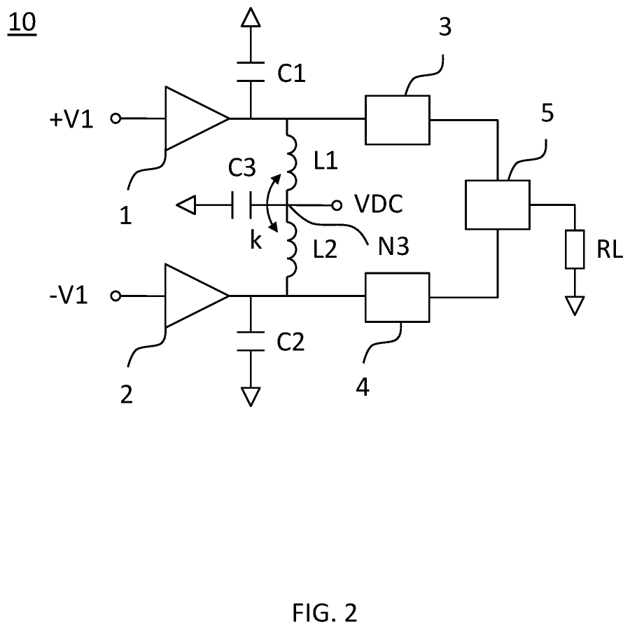

FIG. 2 illustrates a push-pull amplifying unit in accordance with the present invention;

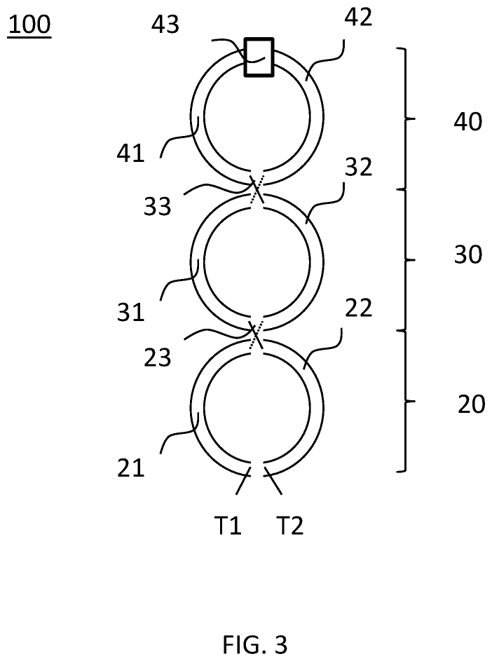

FIG. 3 illustrates an implementation of the first shunt inductor and second shunt inductor of the amplifying unit in FIG. 2;

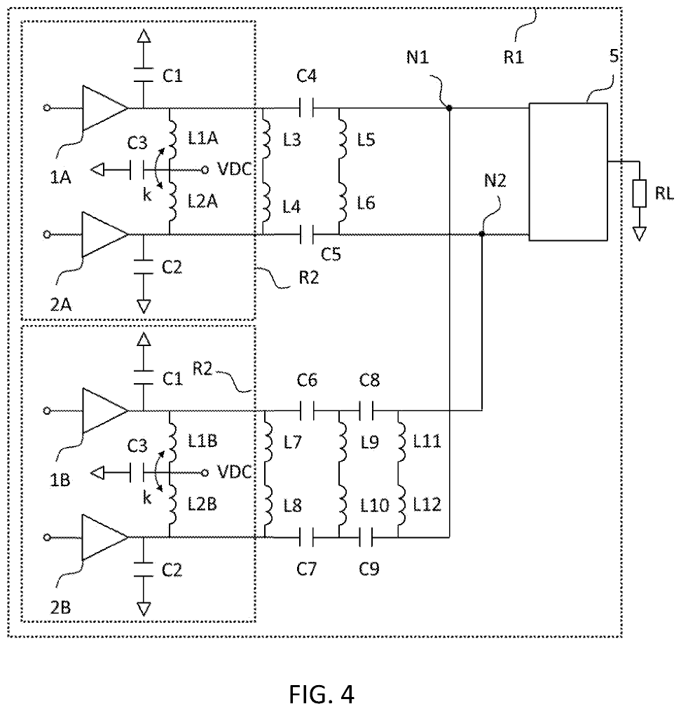

FIG. 4 illustrates an implementation of a balanced two-way Doherty amplifier using amplifying unit 10 of FIG. 2;

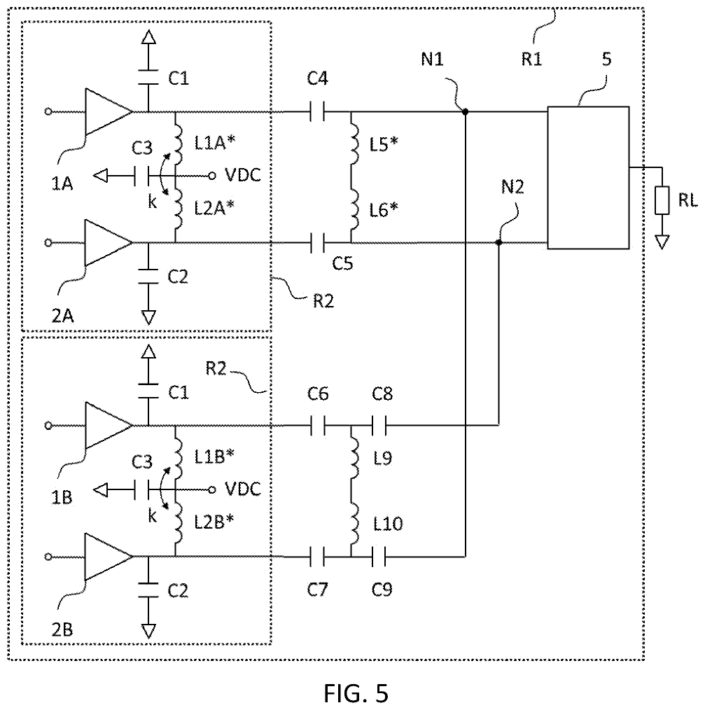

FIG. 5 is a reduction in space of the implementation of FIG. 4;

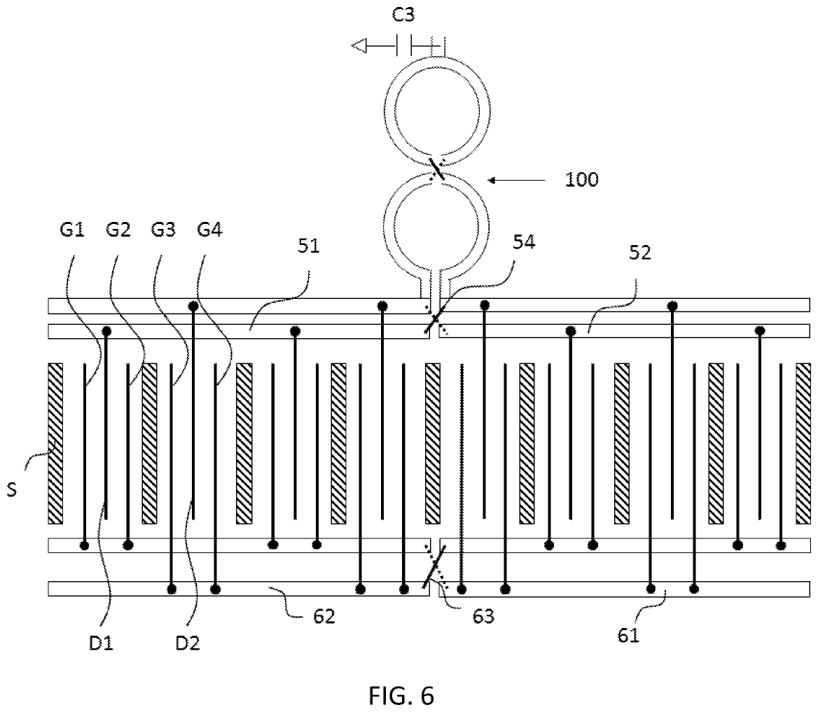

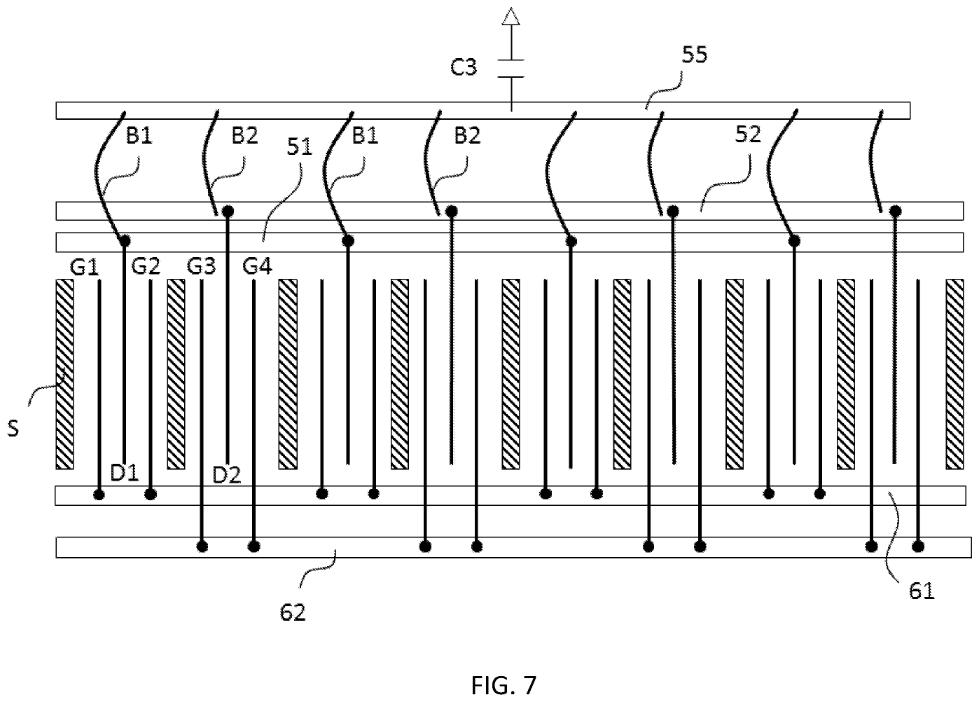

FIGS. 6 and 7 are possible layouts of the amplifying unit of FIG. 2.

FIG. 1 illustrates a known example of a balanced 2-way Doherty amplifier. This amplifier comprises a primary main amplifier M1, a secondary main amplifier M2, a primary peak amplifier P1, and a secondary peak amplifier P2. The single-ended signal to be amplified by the Doherty amplifier is first provided to the unbalanced port of an input balun (not shown) that splits the signal into a signal part emerging from its first balanced output port and a signal part emerging from its second balanced output port, wherein the signal part emerging from the second balanced output port has a phase delay of 180 degrees relative to the signal part emerging from the first balanced output port. These signal parts are then provided to respective Doherty splitters. A first Doherty splitter splits the signal part emerging from the first balanced output port into a first signal part and a third signal part and feeds these parts to primary main amplifier M1 and primary peak amplifier P1, respectively. A second Doherty splitter splits the signal part emerging from the second balanced output port into a second signal part and a fourth signal part and feeds these parts to secondary main amplifier M2 and secondary peak amplifier P2, respectively.

The output of primary main amplifier M1 is connected through a first quarter wavelength transmission line with characteristic impedance Z01 to a first combining node N1. The output of secondary main amplifier M2 is connected through a first quarter wavelength transmission line with characteristic impedance Z01 to a second combining node N2.

The output of primary peak amplifier P1 is connected to second combining node N2 through a second quarter wavelength transmission line with characteristic impedance Z02 and a third quarter wavelength transmission line with characteristic impedance Z03. The output of secondary peak amplifier P2 is connected to second combining node N1 through a second quarter wavelength transmission line with characteristic impedance Z02 and a third quarter wavelength transmission line with characteristic impedance Z03. At combining node N1, the signals from primary main amplifier M1 and secondary peak amplifier P2 add in-phase to form a first combined signal. At combining node N2, the signals from secondary main amplifier M2 and primary peak amplifier P1 add in-phase to form a second combined signal, which has a phase offset of 180 degrees relative to the first combined signal.

The first combined signal is fed to a first balanced input port of a balun 5 and the second combined signal is fed to a second balanced input port of balun 5. At the unbalanced output port of balun 5, a single-ended signal will emerge that is fed to a load impedance RL.

The known balanced 2-way Doherty amplifier of FIG. 1 has several drawbacks. Firstly, the quarter wavelength transmission lines require a considerable amount of area. Secondly, it is difficult to achieve proper harmonic terminations at the output of amplifiers M1, M2, P1, and P2. These problems are complicated due to the presence of DC biasing networks (not shown) that are required to provide biasing to the outputs of M1, M2, P1, and P2.

A push-pull amplifying unit that addresses these problems is shown in FIG. 2. Here, an amplifying unit 10 is shown that comprises a first amplifier 1 and a second amplifier 2. First amplifier 1 has an output capacitance C1 and second amplifier 2 has an output capacitance C2. First amplifier 1 and a second amplifier 2 may for example correspond to a silicon based laterally diffused metal-oxide-semiconductor, LDMOS, transistor or to a gallium nitride field-effect transistor. Moreover, amplifiers 1, 2 can be arranged on a single semiconductor die. Alternatively, amplifiers 1, 2 are arranged on separate semiconductor dies that may or may not be packaged.

First amplifier 1 has a first output that is connected to a first matching network 3 and second amplifier 2 has a second output that is connected to a second matching network 4. Outputs of matching networks 3, 4 are combined into a single-ended output signal by an output balun 5. The output signal is fed to a load RL.

Biasing of amplifiers 1,2 is obtained through a first shunt inductor L1 that is connected between the first output and node N3 and a second shunt inductor L2 that is connected between the second output and node N3. First shunt inductor L1 and second shunt inductor L2 are inductively coupled as indicated by coupling coefficient k.

A capacitor C3 is connected to node N3. Capacitor C3 is configured to provide a short at RF frequencies. A DC biasing source VDC is connected to N3 through a feed line (not shown).

Amplifiers 1, 2 are fed by preferably identical signals having a mutual phase offset of 180 degrees. The voltage V1 at the first output looking and the voltage V2 at the second output can be described using:

V1=jωL1I₁+jωMI₂

V2=jωL1I₂+jωMI₁

where I₁ is the current from the first output towards node N3, I₂ the current from the second output towards node N3, and M the coefficient of mutual induction that can be computed using:

M=k\sqrt{L1L2}

Amplifiers 1, 2 are generally non-linear devices. Consequently, second and third order products will emerge at the first and second output. Moreover, typically L1=L2.

At the fundamental frequency, voltage V1 at the first output will have a 180 degrees phase offset relative to voltage V2 at the second output. Node N3 will then act as a virtual ground. Hereinafter, a node acting as a virtual ground at the fundamental frequency will simply be referred to as virtual ground. It should however be noted that such node may also be connected to ground.

Because at the fundamental frequency I1=−I2, impedance Z1 looking from the first output towards node N3 and impedance Z2 looking from the second output towards node N3 can be computed using:

Z1=Z2=jωL−jωM=jωL1(1−k)

However, at the second harmonic frequency, voltage V1 at the first output will be in phase with voltage V2. Consequently, I1=I2, thereby resulting in:

Z1=Z2=jωL1+jωM=jωL1(1+k)

In case of a negative coupling coefficient k, an increase of Z1 and Z2 is achieved at the fundamental frequency relative to the contribution of L1 or L2 in isolation, i.e. without inductive coupling. At the second harmonic frequency however, a decrease is achieved. It is therefore possible to simultaneously tune the output impedance at the first and second output at the fundamental frequency whereas at the same time presenting a low impedance at the second harmonic frequency or any other even harmonic frequency.

Furthermore, a substantially real impedance may be presented at the intrinsic output of amplifiers 1, 2, i.e. at the drains of amplifiers 1, 2 by choosing L1 and L2 such that output capacitances C1 and C2 are tuned out:

$$L 1 C 1 = {( \frac{1}{{ω}_{1}} )}^{2} and L 2 C 2 = {( \frac{1}{{ω}_{1}} )}^{2}$$

where ω₁ is a frequency at or close to the fundamental frequency of the signal to be amplified.

Typically, the fundamental frequency of the signal to be amplified lies in a frequency range between 10 MHz and 40 GHz, more in particular in frequency bands allocated for mobile telecommunications such as 4G, 5G, or 6G.

As demonstrated above, first shunt inductor L1 and second shunt inductor L2 allow simultaneous tuning of the second harmonic impedance and the fundamental impedance. Furthermore, because node N3 acts as a virtual ground it becomes possible to connect a DC biasing network without impacting RF behavior at the fundamental frequency.

FIG. 3 illustrates an implementation of the first shunt inductor and second shunt inductor of amplifying unit 10. More in particular, first shunt inductor L1 and second shunt inductor L2 are formed by a chain 100 of three loop units 20, 30, 40. Loop unit 20 comprises a first loop part 21 having a first end that forms a first terminal T1 of first shunt inductor L1, and a second loop part 22 having a third end that forms a first terminal T2 of second shunt inductor L2. At the upper side, first loop part 21 comprises a second end, and second loop part 22 a fourth end.

Loop unit 20 is connected to loop unit 30 using cross connection 23. Typically, cross connection 23 can be formed using different layers of a metal layer stack or a bridging technology, such as an air bridge.

Cross connection 23 connects second end of first loop part 21 to the third end of second loop part 32 and connects fourth end of second loop part 22 to the first end of first loop part 31. At the opposite side of loop unit 30, the second end of first loop part 31 is connected, through cross connection 33, to the third end of second loop part 42, and the fourth end of second loop part 32 is connected to the first end of first loop part 41. The second end of first loop part 41 is connected to the fourth end of second loop part 42. This connection is illustrated in FIG. 3 using connecting element 43, which may be separate element, or which is a particular region of loop unit 40 in which the second end and fourth end are integrally connected. Connecting element 43 corresponds to node N3 in FIG. 2.

An advantage of the chain of loop units shown in FIG. 3 is that access terminals T1 and T2 are formed at a same side. As will be explained later in connection with FIGS. 6 and 7, this may prove advantageous for achieving a compact solution.

FIG. 4 illustrates an implementation of a balanced two-way Doherty amplifier using amplifying unit 10 of FIG. 2. Signals to be fed to the various amplifiers 1A, 2A, 1B, 2B may have a similar phase relationship as depicted in FIG. 1. Furthermore, the various quarter wavelength transmission lines of the embodiment in FIG. 1 have been replaced by first networks and second networks. The first output of primary main amplifier 1A is connected to a first network that comprises an input shunt inductor L3, a series capacitor C4, and an output shunt inductor L5. The second output of secondary main amplifier 2A is connected to a first network that comprises an input shunt inductor L4, a series capacitor C5, and an output shunt inductor L6. Moreover, input shunt inductors L3 and L4, and output shunt inductors L5 and L6, are electrically connected at a virtual ground.

Similarly, the first output of primary peak amplifier 1B is connected to a primary second network that comprises an input shunt inductor L7, a series capacitor C6, and an output shunt inductor L9. The primary second network is connected to combining node N2 through a secondary second network. This latter network comprises an input shunt inductor L9, a series capacitor C8, and an output shunt inductor L11. Here, it is noted that shunt inductor L9 acts as the output shunt inductor for the primary second network and as the input shunt inductor for the secondary second network.

Similarly, the second output of secondary peak amplifier 2B is connected to a primary second network that comprises an input shunt inductor L8, a series capacitor C7, and an output shunt inductor L10. The primary second network is connected to combining node N1 through a secondary second network. This latter network comprises an input shunt inductor L10, a series capacitor C9, and an output shunt inductor L12. Here, it is noted that shunt inductor L10 acts as the output shunt inductor for the primary second network and as the input shunt inductor for the secondary second network. Moreover, shunt inductors L7 and L8, shunt inductors L9 and L10, and shunt inductors L11 and L12 are electrically connected at a virtual ground.

As can be observed from FIG. 4, various shunt inductors are arranged in parallel. For example, shunt inductors L1A and L3, shunt inductors L2A and L4, shunt inductors L5 and L12, shunt inductors L6 and L11, shunt inductors L1B and L7, and shunt inductors L2B and L8. As such, these parallel inductors can be replaced by a single shunt inductor thereby considerably saving occupied area. An example thereof is shown in FIG. 5. For example, inductors L1A and L3 can be combined into an inductor L1A*, inductors L1B and L7 can be combined into an inductor L1B*, inductors L2A and L4 can be combined into an inductor L2A*, inductors L2B and L8 can be combined into an inductor L2B*, inductors L5 and L12 can be combined into an inductor L5*, and inductors L6 and L11 can be combined into an inductor L6*.

Balun 5 can be formed using coupled lines, such as broadside coupled lines or edge coupled lines. For example, balun 5 can be a Marchand balun. Alternatively, balun 5 is formed as two coupled inductors. In general, balun 5 comprises a first inductive part arranged between the first balanced input and the second balanced input of balun 5 and a second inductive part having one terminal connected to ground and another terminal to the output of the Doherty amplifier. As the first inductive part is parallel to shunt inductors L5 and L6 in FIG. 5, it is possible to combine this first inductive part with shunt inductors L5 and L6 further reducing occupied area.

Alternatively, the unbalanced port can be connected to a load that has a capacitive part. For example, the load may be formed by a resistive load that is arranged in series with a capacitor. In this case, an input impedance of the balun between the first and second balanced ports due to the capacitive part has an inductive part. This inductive part may at least partially form shunt inductors L5 and L6, thereby further saving occupied area.

It should be apparent to the skilled person that the various occupied area reducing steps may be used in isolation as well as in combination.

In a different embodiment, the second networks are omitted altogether. In this case, the first output of primary peak amplifier 1B is directly connected combining node N2 and the second output of secondary peak amplifier 2B is directly connected combining node N1.

FIGS. 6 and 7 are possible layouts of the amplifying unit of FIG. 2. In these layouts, the first amplifier and second amplifier are arranged on a single semiconductor die in an interleaved manner. More in particular, each of these amplifiers is configured as a multi-finger field-effect transistor, wherein gate runners corresponding to the multi-finger field-effect transistor of the first amplifier are connected to a first gate terminal 61, gate runners corresponding to the multi-finger field-effect transistor of the second amplifier to a second gate terminal 62, drains corresponding to the multi-finger field-effect transistor of the first amplifier to a first drain terminal 51, and drains corresponding to the multi-finger field-effect transistor of the second amplifier to a second drain terminal 52. As shown in FIGS. 6 and 7, drain terminals 51 and 52 each comprise two parts that are connected using cross connection 53. Moreover, first drain terminal 51 is electrically connected to the first terminal of first shunt inductor L1, and second drain terminal 52 is electrically connected to the first terminal of second shunt inductor L2 Similarly, gate terminals 61 and 62 each comprise two parts that are connected using cross connection 63.

The layouts in FIGS. 6 and 7 differ in the manner in which shunt inductors L1 and L2 are implemented. In FIG. 6, these inductors are realized using a chain 100 of loop units similar to that shown in FIG. 3 albeit only using two loop units. In FIG. 7, shunt inductors L1 and L2 are formed using a first plurality of bondwires B1 and a second plurality of bondwires B2, respectively, which extend between drain terminals 51, 52 and a bond bar 55. In both cases, a capacitor C3 to ground and optionally a DC source is/are connected at the point where L1 and L2 are connected similar to that shown in FIG. 2. In FIG. 7, this point corresponds to bond bar 55. Moreover, in FIG. 7, cross connections such as cross connections 53, 63 may equally be used to facilitate a different access to the gate and drain terminals of the first and second amplifiers.

The remaining circuitry of FIG. 2 can be formed on the same semiconductor die or a different semiconductor die, such as a low-cost passive semiconductor die. Alternatively, the semiconductor die is packaged at the remaining circuitry is realized on a printed circuit board on which the packaged semiconductor die is arranged.

In addition, the layout of FIGS. 6 and 7 can be used for realizing the embodiments of FIGS. 4 and 5. In a particular embodiment, the components indicated by the dashed rectangle R1 are implemented on a single semiconductor die. Alternatively, the components indicated by dashed rectangles are implemented on respective semiconductor dies.

Furthermore, the general aspects of the Doherty amplifier shown in FIG. 1, e.g. the input balun and the Doherty splitters, equally apply to the embodiments of the present invention.

In the above, the present invention has been described using detailed embodiments thereof. However, the skilled person will readily understand that various modifications are possible without deviating from the scope of the present application, which is defined by the appended claims and their equivalents. For example, various aspects of the present invention can be described by the following numbered clauses:

Clause 1. A push-pull amplifying unit, comprising:
a first amplifier having a first output;
a second amplifier having a second output;
a first shunt inductor having a first terminal thereof connected to the first output;
a second shunt inductor having a first terminal thereof connected to the second output, wherein the first and second shunt inductors each have a second terminal, wherein the second terminals of the first and second shunt inductors are electrically connected at a virtual RF ground, which, during use, is RF grounded;
wherein the first and second shunt inductors are inductively coupled to:
   increase the impedance between the first output and the virtual ground and the impedance between the second output and the virtual ground at a fundamental frequency of a signal to be amplified by the push-pull amplifying unit relative to those impedances in the absence of said inductive coupling; and
   decrease the impedance between the first output and the virtual ground and the impedance between the second output and the virtual ground at a second harmonic frequency of the signal to be amplified relative to those impedances in the absence of said inductive coupling.

Clause 2. The push-pull amplifying unit according to clause 1, wherein the inductive coupling between the first shunt inductor and the second shunt inductor is described by a mutual inductance of which a coupling coefficient has a magnitude of at least 0.5, more preferably, 0.7 and even more preferably 0.9.

Clause 3. The push-pull amplifying unit according to clause 1 or 2, wherein the first amplifier comprises a first output capacitance, and wherein the second amplifier comprises a second output capacitance, wherein the first shunt inductor is configured to resonate with the first output capacitance at a frequency at or close to the fundamental frequency of the signal to be amplified, and wherein the second shunt inductor is configured to resonate with the second output capacitance at a frequency at or close to the fundamental frequency of the signal to be amplified.

Clause 4. The push-pull amplifying unit according to any of the previous clauses, wherein the first shunt inductor and the second shunt inductor are formed by one or more loop units connected in a chain of loop units in an order from a first loop unit to a last loop unit, each loop unit comprising a first loop part having a first end and a second end, and a second loop part having a third end and a fourth end, the first and second loop parts being arranged opposite to each other in a respective first direction;
wherein among the one or more loop units, the first end of the first loop part of a first loop unit in the chain of loop units forms the first terminal of the first shunt inductor and the third end of the second loop part of the first loop unit forms the first terminal of the second shunt inductor;
wherein among the one or more loop units, the second end of the first loop part of a last loop unit in the chain of loop units is electrically connected to the fourth end of the second loop part of the last loop unit for forming the virtual RF ground;
wherein for each given loop unit among the one or more loop units other than the last loop unit:
   each second end of the first loop part is electrically connected to the third end of the second loop part of a loop unit that directly follows said given loop unit in the chain of loop units, and each fourth end of the second loop part is electrically connected to the first end of the first loop part of the loop unit that directly follows said given loop unit in the chain of loop units;
   the first loop part is arranged adjacent, in a second direction perpendicular to the first direction, to a second loop part of the loop unit that directly follows said given loop unit in the chain of loop units.

Clause 5. The push-pull amplifying unit according to clause 4, wherein each pair of directly following loop units in the chain of loop units is 8-shaped.

Clause 6. The push-pull amplifying unit according to any of the clauses 1-3, wherein the first shunt inductor comprises a first horizontally extending planar loop part and wherein the second shunt inductor comprises a second horizontally extending planar loop part, wherein the first and second planar loop parts are vertically spaced apart and are at least partially horizontally overlapping.

Clause 7. The push-pull amplifying unit according to any of the clauses 1-3, wherein the first shunt inductor and the second shunt inductor are each formed by one or more bondwires, wherein the one or more bondwires of the first shunt inductor preferably extend parallel to the one or more bondwires of the second inductor.

Clause 8. The push-pull amplifying unit according to any of the previous clauses, further comprising a semiconductor die on which the first amplifier and second amplifier are integrated, each of the first and second amplifier being formed as a multi-finger field-effect transistor, wherein the field-effect transistors of the first amplifier and second amplifier are interleaved, wherein gate runners corresponding to the multi-finger field-effect transistor of the first amplifier are connected to a first gate terminal, gate runners corresponding to the multi-finger field-effect transistor of the second amplifier to a second gate terminal, drains corresponding to the multi-finger field-effect transistor of the first amplifier to a first drain terminal, and drains corresponding to the multi-finger field-effect transistor of the second amplifier to a second drain terminal;
wherein the first drain terminal is electrically connected to the first terminal of the first shunt inductor, and wherein the second drain terminal is electrically connected to the first terminal of the second shunt inductor.

Clause 9. The push-pull amplifying unit according to any of the previous clauses, wherein the first drain terminal, the second drain terminal, the first gate terminal, and the second gate terminal, are each formed by rectangular bars that are elongated in a direction perpendicular to the gate runners of the multi-finger field-effect transistors of the first amplifier and second amplifier.

Clause 10. The push-pull amplifying unit according to any of the previous clauses, further comprising a DC biasing network connected to the virtual RF ground and configured for supplying a DC bias to the first output and second output.

Clause 11. The push-pull amplifying unit according to any of the previous clauses, wherein the DC biasing network comprises a shunt capacitor arranged in between the virtual ground and ground and configured for providing a short at RF frequencies, and a feeding line that is connected or connectable to a DC biasing source.

Clause 12. The push-pull amplifying unit according to any of the previous clauses, further comprising an input balun having an unbalanced input port for receiving the signal to be amplified, a first balanced output port connected to an input of the first amplifier, and a second balanced output port connected to an input of the second amplifier.

Clause 13. A Doherty amplifier, comprising:
a main amplifier comprising a push-pull amplifying unit as defined in any of the previous clauses;
a peak amplifier comprising a push-pull amplifying unit as defined in any of the previous clauses;
a first impedance inverter connected between a first combining node and the first output of the push-pull amplifying unit of one of the main amplifier and peak amplifier;
a second impedance inverter connected between a second combining node and the second output of the push-pull amplifying unit of said one of the main amplifier and peak amplifier;
a balun having a first balanced input connected to the first combining node, a second balanced input connected to the second combining node, and an unbalanced output connected to an output of the Doherty amplifier;
wherein the second output of the push-pull amplifying unit of the other of said main amplifier and peak amplifier is electrically connected to the first combining node; and
wherein the first output of the push-pull amplifying unit of said the other of said main amplifier and peak amplifier is connected to the second combining node.

Clause 14. The Doherty amplifier according to clause 13, comprising a Doherty splitter configured to split a signal to be amplified into a first signal part and a second signal part, wherein the second signal part has a phase offset of 90 degrees relative to the second signal part.

Clause 15. The Doherty amplifier according to clause 14, further comprising a first input balun and a second input balun, wherein the first input balun has an unbalanced input port for receiving the first signal part from the Doherty splitter, the first input balun being configured for outputting a signal emerging at its first balanced output port to the first amplifier of the amplifying unit of the main amplifier, and for outputting a signal emerging at its second balanced output port to the second amplifier of the amplifying unit of the main amplifier;
wherein the second input balun has an unbalanced input port for receiving the second signal part from the Doherty splitter, the second input balun being configured for outputting a signal emerging at its first balanced output port to the first amplifier of the amplifying unit of the peak amplifier, and for outputting a signal emerging at its second balanced output port to the second amplifier of the amplifying unit of the peak amplifier.

Clause 16. The Doherty amplifier according to any of the clauses 13-15, wherein the first impedance inverter and the second impedance inverter are each formed by a respective first network, each first network comprising an input shunt inductor between an input node of the first network and the virtual ground or ground, a series capacitor between the input node and an output node of the first network, and an output shunt inductor between the output node and the virtual ground or ground.

Clause 17. The Doherty amplifier according to clause 16, wherein the input shunt inductor of the first network of the first impedance inverter is electrically connected to the input shunt inductor of the first network of the second impedance inverter; and/or
wherein the output shunt inductor of the first network of the first impedance inverter is electrically connected to the output shunt inductor of the first network of the second impedance inverter.

Clause 18. The Doherty amplifier according to clause 17, wherein the connected input shunt inductors or the connected output shunt inductors are formed by a chain of loop units as defined in any of the clauses 4-5.

Clause 19. The Doherty amplifier according to clause 18, wherein the connected input shunt inductors are incorporated in the first shunt inductor and second shunt inductor.

Clause 20. The Doherty amplifier according to any of the clauses 13-19, further comprising one or more second networks arranged in between the first output of the push-pull amplifying unit of the other of the main amplifier and peak amplifier, and the second combining node, and one or more second networks arranged in between the second output of the push-pull amplifying unit of the other of the main amplifier and peak amplifier and the first combining node, each second network comprising an input shunt inductor between an input node of the second network and the virtual ground or ground, a series capacitor between the input node and an output node of the second network, and an output shunt inductor between the output node of the second network and the virtual ground or ground.

Clause 21. The Doherty amplifier according to clause 20, wherein the input shunt inductor of that second network which is connected to the first output of the push-pull amplifying unit of the other of the main amplifier and peak amplifier and the input shunt inductor of that second network which is connected to the second output of the push-pull amplifying unit of the other of the main amplifier and peak amplifier are electrically connected; and/or
wherein the output shunt inductor of that second network which is connected to the first combining node and the output shunt inductor of that second network which is connected to the second combining node are electrically connected.

Clause 22. The Doherty amplifier according to clause 21, wherein the connected input shunt inductors of the second networks and/or the connected output shunt inductors of the second networks are formed by a chain of loop units as defined in any of the clauses 4-5.

Clause 23. The Doherty amplifier according to clause 22, wherein the connected input shunt inductors of the second networks are incorporated in the first shunt inductor and second shunt inductor of the push-pull amplifying unit of the other of the main amplifier and peak amplifier.

Clause 24. The Doherty amplifier according to any of the clauses 17-23 in so far as depending on clause 21, wherein the connected output shunt inductors of the second networks and the connected output shunt inductors of the first networks are combined.

Clause 25. The Doherty amplifier according to any of the clauses 13-24, wherein the balun comprises a first inductive part arranged between the first balanced input and the second balanced input, and a second inductive part having one terminal connected to ground and another terminal to the output of the Doherty amplifier, said second inductive part being electromagnetically coupled with the first inductive part.

Clause 26. The Doherty amplifier according to clause 25, wherein the first inductive part is combined with the connected output shunt inductors of the first networks and/or the connected output shunt inductors of the second networks.

Clause 27. The Doherty amplifier according to clause 26, wherein the unbalanced port is connected to a load having a capacitive part, wherein an input impedance of the balun between the first and second balanced ports due to the capacitive part has a inductive part that at least partially forms the connected output shunt inductors of the first networks and/or the connected output shunt inductors of the second networks.

1. A Doherty amplifier, comprising:
a main amplifier comprising a first push-pull amplifying unit, and a peak amplifier comprising a second push-pull amplifying unit, wherein each of the first and second push-pull amplifying unit comprises:
a first amplifier having a first output;
a second amplifier having a second output;
a parallel connection of a primary first shunt inductor part and a secondary first shunt inductor part, which parts are embodied as a single first shunt inductor having a first terminal thereof connected to the first output; and
a parallel connection of a primary second shunt inductor part and a secondary second shunt inductor part, which parts are embodied as a single second shunt inductor having a first terminal thereof connected to the second output;
the Doherty amplifier further comprising:
a first impedance inverter connected between a first combining node and the first output of the push-pull amplifying unit of one of the main amplifier and peak amplifier, wherein the second output of the push-pull amplifying unit of the other of said main amplifier and peak amplifier is electrically connected to the first combining node;
a second impedance inverter connected between a second combining node and a second output of the push-pull amplifying unit of said one of the main amplifier and peak amplifier, wherein a first output of the push-pull amplifying unit of said the other of said main amplifier and peak amplifier is connected to the second combining node;
one or more second networks arranged in between the first output of the push-pull amplifying unit of the other of the main amplifier and peak amplifier, and the second combining node, and one or more second networks arranged in between the second output of the push-pull amplifying unit of the other of the main amplifier and peak amplifier and the first combining node, each second network comprising an input shunt inductor between an input node of the second network and the virtual ground or ground, a series capacitor between the input node and an output node of the second network, and an output shunt inductor between the output node of the second network and the virtual ground or ground; and
a balun having a first balanced input connected to the first combining node, a second balanced input connected to the second combining node, and an unbalanced output connected to an output of the Doherty amplifier,
wherein the first and second shunt inductors each have a second terminal, wherein the second terminals of the first and second shunt inductors are electrically connected at a virtual RF ground, which, during use, is RF grounded,
wherein the first and second shunt inductors are inductively coupled to:
increase the impedance between the first output and the virtual ground and the impedance between the second output and the virtual ground at a fundamental frequency of a signal to be amplified by the push-pull amplifying unit relative to those impedances in the absence of said inductive coupling; and
decrease the impedance between the first output and the virtual ground and the impedance between the second output and the virtual ground at a second harmonic frequency of the signal to be amplified relative to those impedances in the absence of said inductive coupling,
wherein the first amplifier comprises a first output capacitance, wherein the second amplifier comprises a second output capacitance, wherein the primary first shunt inductor part is configured to resonate with the first output capacitance at a frequency at or close to the fundamental frequency of the signal to be amplified, wherein the primary second shunt inductor part is configured to resonate with the second output capacitance at a frequency at or close to the fundamental frequency of the signal to be amplified,
wherein the first impedance inverter and the second impedance inverter are each formed by a respective first network, each first network comprising an input shunt inductor between an input node of the first network and the virtual ground or ground, a series capacitor between the input node and an output node of the first network, and an output shunt inductor between the output node and the virtual ground or ground,
wherein the input shunt inductor of the first impedance inverter is formed by the secondary first inductor part, wherein the input shunt inductor of the second impedance inverter is formed by the secondary second inductor part,
wherein the input shunt inductor of that second network that is connected to the first output of the push-pull amplifying unit of the other of the main amplifier and peak amplifier is formed by the secondary first inductor part of the first shunt inductor of that push-pull amplifying unit, and wherein the input shunt inductor of that second network that is connected to the second output of the push-pull amplifying unit of the other of the main amplifier and peak amplifier is formed by the secondary second inductor part (b of the second shunt inductor of that push-pull amplifying unit.

2. The Doherty amplifier according to claim 1, wherein, for the first or second push-pull amplifying unit the inductive coupling between the primary first shunt inductor part and the primary second shunt inductor part is described by a mutual inductance of which a coupling coefficient has a magnitude of at least 0.5.

3. The Doherty amplifier according to claim 1, wherein, for the first or second amplifying unit:
the first shunt inductor and the second shunt inductor are formed by one or more loop units connected in a chain of loop units in an order from a first loop unit to a last loop unit, each loop unit comprising a first loop part having a first end and a second end, and a second loop part having a third end and a fourth end, the first and second loop parts being arranged opposite to each other in a respective first direction;
among the one or more loop units, the first end of the first loop part of a first loop unit in the chain of loop units forms the first terminal of the first shunt inductor and the third end of the second loop part of the first loop unit forms the first terminal of the second shunt inductor;
among the one or more loop units, the second end of the first loop part of a last loop unit in the chain of loop units is electrically connected to the fourth end of the second loop part of the last loop unit for forming the virtual RF ground;
for each given loop unit among the one or more loop units other than the last loop unit:
each second end of the first loop part is electrically connected to the third end of the second loop part of a loop unit that directly follows said given loop unit in the chain of loop units, and each fourth end of the second loop part is electrically connected to the first end of the first loop part of the loop unit that directly follows said given loop unit in the chain of loop units;
the first loop part is arranged adjacent, in a second direction perpendicular to the first direction, to a second loop part of the loop unit that directly follows said given loop unit in the chain of loop units.

4. The Doherty amplifier according to claim 3, wherein, for the first or second push-pull amplifying unit each pair of directly following loop units in the chain of loop units is 8-shaped.

5. The Doherty amplifier according to claim 1, wherein, for the first or second push-pull amplifying unit:
the first shunt inductor comprises a first horizontally extending planar loop part and the second shunt inductor comprises a second horizontally extending planar loop part, and the first and second planar loop parts are vertically spaced apart and are at least partially horizontally overlapping.

6. The Doherty amplifier according to claim 1, wherein, for the first or second push-pull amplifying unit the first shunt inductor and the second shunt inductor are each formed by one or more bondwires, and wherein the one or more bondwires of the first shunt inductor extend parallel to the one or more bondwires of the second inductor.

7. The Doherty amplifier according to claim 1, wherein the first or second push-pull amplifying unit further comprise a semiconductor die on which the first amplifier and second amplifier are integrated, each of the first and second amplifier being formed as a multi-finger field-effect transistor, wherein the field-effect transistors of the first amplifier and second amplifier are interleaved, wherein gate runners corresponding to the multi-finger field-effect transistor of the first amplifier are connected to a first gate terminal, gate runners corresponding to the multi-finger field-effect transistor of the second amplifier to a second gate terminal, drains corresponding to the multi-finger field-effect transistor of the first amplifier to a first drain terminal, and drains corresponding to the multi-finger field-effect transistor of the second amplifier to a second drain terminal,
wherein the first drain terminal is electrically connected to the first terminal of the first shunt inductor, and wherein the second drain terminal is electrically connected to the first terminal of the second shunt inductor.

8. The Doherty amplifier according to claim 7, wherein, for the first or second push-pull amplifying unit the first drain terminal, the second drain terminal, the first gate terminal, and the second gate terminal, are each formed by rectangular bars that are elongated in a direction perpendicular to the gate runners of the multi-finger field-effect transistors of the first amplifier and second amplifier.

9. The Doherty amplifier according to claim 1, wherein the first or second push-pull amplifying unit further comprises a DC biasing network connected to the virtual RF ground and configured for supplying a DC bias to the first output and second output.

10. The Doherty amplifier according to claim 9, wherein the DC biasing network comprises a shunt capacitor arranged in between the virtual ground and ground and configured for providing a short at RF frequencies, and a feeding line that is connected or connectable to a DC biasing source.

11. The Doherty amplifier according to claim 1, wherein the first or second push-pull amplifying unit further comprises an input balun having an unbalanced input port for receiving the signal to be amplified, a first balanced output port connected to an input of the first amplifier, and a second balanced output port connected to an input of the second amplifier.

12. The Doherty amplifier according to claim 1, comprising a Doherty splitter configured to split a signal to be amplified into a first signal part and a second signal part, wherein the second signal part has a phase offset of 90 degrees relative to the second signal part.

13. The Doherty amplifier according to claim 12, further comprising a first input balun and a second input balun, wherein the first input balun has an unbalanced input port for receiving the first signal part from the Doherty splitter, the first input balun being configured for outputting a signal emerging at its first balanced output port to the first amplifier of the amplifying unit of the main amplifier, and for outputting a signal emerging at its second balanced output port to the second amplifier of the amplifying unit of the main amplifier, and
wherein the second input balun has an unbalanced input port for receiving the second signal part from the Doherty splitter, the second input balun being configured for outputting a signal emerging at its first balanced output port to the first amplifier of the amplifying unit of the peak amplifier, and for outputting a signal emerging at its second balanced output port to the second amplifier of the amplifying unit of the peak amplifier.

14. The Doherty amplifier according to claim 1, wherein the output shunt inductor of the first network of the first impedance inverter is electrically connected to the output shunt inductor of the first network of the second impedance inverter.

15. The Doherty amplifier according to claim 1, wherein the output shunt inductor of that second network which is connected to the first combining node and the output shunt inductor of that second network which is connected to the second combining node are electrically connected.

16. The Doherty amplifier according to claim 14, wherein the connected output shunt inductors of the second networks and the connected output shunt inductors of the first networks are combined.

17. The Doherty amplifier according to claim 3, wherein the connected input shunt inductors or the connected output shunt inductors are formed by the chain of loop units.

18. The Doherty amplifier according to claim 1, wherein the balun comprises a first inductive part arranged between the first balanced input and the second balanced input, and a second inductive part having one terminal connected to ground and another terminal to the output of the Doherty amplifier, said second inductive part being electromagnetically coupled with the first inductive part.

19. The Doherty amplifier according to claim 18, wherein the first inductive part is combined with the connected output shunt inductors of the first networks or the connected output shunt inductors of the second networks.

20. The Doherty amplifier according to claim 19, wherein the unbalanced port is connected to a load having a capacitive part, and wherein an input impedance of the balun between the first and second balanced ports due to the capacitive part has a inductive part that at least partially forms the connected output shunt inductors of the first networks or the connected output shunt inductors of the second networks.
